(19) United States
(12) Patent Application Publication
(10) Pub. No.: US 2025/0334888 A1
(43) Pub. Date: Oct. 30, 2025

(54) DIGITAL LITHOGRAPHY OVERLAY METROLOGY

(71) Applicant: Applied Materials, Inc., Santa Clara, CA (US)

(72) Inventors: Hwan Joo JEONG, Los Altos, CA (US); Jang Fung CHEN, Cupertino, CA (US); Chun-chih CHUANG, Changhua (TW); Yung Peng HU, Miaoli County 363 (TW)

(21) Appl. No.: 19/077,793

(22) Filed: Mar. 12, 2025

Related U.S. Application Data
(60) Provisional application No. 63/638,529, filed on Apr. 25, 2024.

(51) Int. Cl. G03F 7/00

(52) U.S. Cl. CPC G03F 7/70633; G03F 7/706837

(57) ABSTRACT

Embodiments of the present disclosure provide a method including capturing an image having an alignment mark, rotating the captured image by a first amount to produce a rotated image to determine a center point of the alignment mark and establishing a positional relationship between the rotated image and the captured image. The method further includes separating the alignment mark into a first alignment mark portion and a second alignment mark portion, rotating the first alignment mark portion by the first amount, establishing a positional relationship between the rotated first segment and the first alignment mark portion to determine a center point of the first alignment mark portion, rotating the second alignment mark portion by the first amount, establishing a positional relationship between the rotated second segment and the second alignment mark portion to determine a center point of the second alignment mark portion, and computing an overlay error.

### CROSS-REFERENCE TO RELATED APPLICATIONS

This application claims priority to U.S. Provisional Application No. 63/638,529, filed Apr. 25, 2024, the entire disclosure of which is hereby incorporated by reference herein.

### BACKGROUND

### Field

Embodiments described herein generally relate to lithography systems. More specifically, embodiments described herein relate to determining overlay errors in digital lithography systems.

### Description of the Related Art

Microlithography techniques are generally employed to create electrical features on a substrate. A light-sensitive photoresist is typically applied to at least one surface of the substrate. Then, either a photolithography mask or pattern generator like a micro-mirror array exposes selected areas of the light sensitive photoresist as part of a pattern. Light causes chemical changes to the photoresist in the selected areas to prepare these selected areas for subsequent material removal and/or material addition processes to create the electrical features. The precise placement of the electrical features upon the substrate determines the quality of the electrical interconnections.

Alignment techniques are implemented during manufacturing processes to ensure correct alignment of the various layers with one another. Typically, alignment marks are utilized in the layers to assist in the alignment of features in different layers. An increased accuracy in identification of a location of the alignment mark(s) may provide a more accurate alignment of the layers and therefore reduction in the overlay error.

Accordingly, what is needed in the art are improved methodologies for accurately aligning material layers.

### SUMMARY

Embodiments of the present disclosure provide a method including capturing an image having an alignment mark, determining a center point of the alignment mark, by rotating the image by a first amount and correlating it with the original or non-rotated image. The method further includes separating the alignment mark into a first alignment mark portion located on a first segment of the image and a second alignment mark portion located on a second segment of the image, rotating the first segment of the image including the first alignment mark portion by the first amount and correlating it with the non-rotated first segment of the image to determine a center point of the first alignment mark portion, rotating the second segment of the image including the second alignment mark portion by the first amount and correlating it with the non-rotated second segment of the image to determine a center point of the second alignment mark portion, and computing an overlay error by determining a difference between the center point of the first alignment mark portion and the center point of the second alignment mark portion.

Embodiments of the present disclosure provide a non-transitory computer-readable medium comprising instructions that, when executed, cause a lithography system to capture an image having an alignment mark, determine a center point of the alignment mark by rotating the image by a first amount and correlating it with the original or non-rotated) image. The non-transitory computer-readable medium comprises instructions that, when executed, further cause a lithography system to separate the alignment mark into a first alignment mark portion located on a first segment of the image and a second alignment mark portion located on a second segment of the image, rotate the first segment of the image including the first alignment mark portion by the first amount and correlate it with the non-rotated first segment of the image to determine a center point of the first alignment mark portion, rotate the second segment of the image including the second alignment mark portion by the first amount and correlate it with the non-rotated second segment of the image to determine a center point of the second alignment mark portion, and compute an overlay error by determining a difference between the center point of the first alignment mark portion and the center point of the second alignment mark portion.

Embodiments of the present disclosure provide a method including capturing an image having an alignment mark, rotating the image and correlating it with the original or non-rotated image to determine a center point of the alignment mark, separating the alignment mark into a first alignment mark portion and a second alignment mark portion, performing self-correlation on the first alignment mark portion, performing self-correlation on the second alignment mark portion, and computing an overlay error by taking a difference between the position of self-correlation peak on the first alignment mark portion and the position of self-correlation peak on the second alignment mark portion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic partial perspective view of a lithography system, according to one or more of the embodiments described herein.

FIG. 2 is a perspective schematic view of an image projection apparatus used in the lithography system of FIG. 1 during an illumination operation, according to one or more of the embodiments described herein.

FIG. 3 is a schematic of the lithography system of FIG. 1, according to one or more of the embodiments described herein.

FIG. 4A illustrates a target image including an alignment mark, the target image indicating an actual center point of the target image and a predetermined center point of the rotation, according to one or more of the embodiments described herein.

FIG. 4B illustrates the target image of FIG. 4A rotated by a first amount, according to one or more of the embodiments described herein.

FIG. 4C illustrates two times of a deviation between the actual center point of the target image and the predetermined center point of the rotation, according to one or more of the embodiments described herein.

FIG. 5A illustrates a target image including an alignment mark, according to one or more of the embodiments described herein.

FIGS. 5B-5C illustrate separating the target image of FIG. 5A including the alignment mark into a first alignment mark portion and a second alignment mark portion, according to one or more of the embodiments described herein.

FIGS. 5D-5E illustrate performing self-correlation individually to the first alignment mark portion and the second alignment mark portion, according to one or more of the embodiments described herein.

FIG. 6 is a method for computing an overlay error to perform proper alignment of material layers, according to one or more of the embodiments described herein.

FIG. 7 is a method for computing an overlay error between the first alignment mark portion and the second alignment mark portion, according to one or more of the embodiments described herein.

FIG. 8 illustrates a process of establishing positional relationships, according to one or more of the embodiments described herein.

FIG. 9 illustrates a process for determining an overlay measurement employing the positional relationship process three times, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to determining overlay errors in digital lithography systems.

Semiconductors play an important role in the fabrication and manufacture of electronic devices. As such, manufacturers invest technology and time into refining their processes to produce semiconductor chips that are consistently high-quality. Metrology is important to achieving this goal.

TTE metrology, also known as Through-Thickness Electrical (TTE) metrology, is a technique used in semiconductor manufacturing to measure the electrical properties of thin films or layers within a semiconductor device. In semiconductor fabrication, various layers of materials are deposited onto a substrate to form the intricate structures used for the functioning of electronic components. These layers often have specific electrical properties that are critical for the performance of the final device. TTE metrology allows manufacturers to measure these properties through the thickness of the layers. This is important because the properties of thin films may vary across their thickness due to factors such as deposition conditions, material composition, and processing techniques. By measuring through the thickness, manufacturers can ensure that the electrical properties meet the desired specifications at all points within the layer.

TTE-M metrology stands for Through-the-thickness Electrical-Mechanical (TTE-M) metrology. TTE-M is an advanced technique used in semiconductor manufacturing to simultaneously measure both the electrical and mechanical properties of thin films or layers within semiconductor devices. In semiconductor fabrication, the electrical properties of thin films, such as conductivity or resistance, are important for the performance of electronic components. However, mechanical properties, such as stress, strain, and elasticity, also play a role in determining the reliability and performance of semiconductor devices. TTE-M metrology allows manufacturers to characterize both electrical and mechanical properties simultaneously and through the thickness of thin films. By doing so, manufacturers can gain insights into how mechanical stress or strain may affect the electrical performance of the device and vice versa. This information is beneficial for optimizing fabrication processes, improving device reliability, and designing more robust semiconductor devices.

Thus, metrology is beneficial for monitoring and controlling lithography processes. Metrology provides measurements of critical dimensions (CD), overlay, and other parameters used for optimizing lithographic exposure settings and ensuring the accuracy of printed patterns. Metrology techniques are used to inspect photomasks and reticles, which are components of lithography systems. These inspections ensure that the masks are free from defects and accurately represent the intended device patterns. Metrology is employed to measure the features printed on semiconductor substrates during lithography. This includes measuring line widths, spacing, and other dimensions to verify that the lithographic process has achieved the desired geometries accurately. Metrology techniques are used to measure overlay accuracy, which refers to the alignment of different layers of patterns or the alignment between different patterns in the same layer during lithography steps. Precise overlay control is important for ensuring the proper registration of multiple patterns in the same or different layers, which is important for device functionality.

The example embodiments present overlay techniques to measure overlay accuracy when aligning same or different layers of patterns during lithography steps. In one example, the overlay technique involves capturing an image of an alignment mark, rotating the captured image by a first amount, e.g., 180° to determine a center point of the alignment mark, and establishing a positional relationship between the rotated image and the captured image. The establishment of the positional relationship may also be referred to as self-correlation. Further, the overlay technique involves capturing an image of an alignment mark, separating the alignment mark into a first alignment mark portion and a second alignment mark portion, performing self-correlation on the first alignment mark portion, performing self-correlation on the second alignment mark portion, and computing an overlay error by taking a difference between the position of self-correlation peak on the first alignment mark portion and the position of self-correlation peak on the second alignment mark portion.

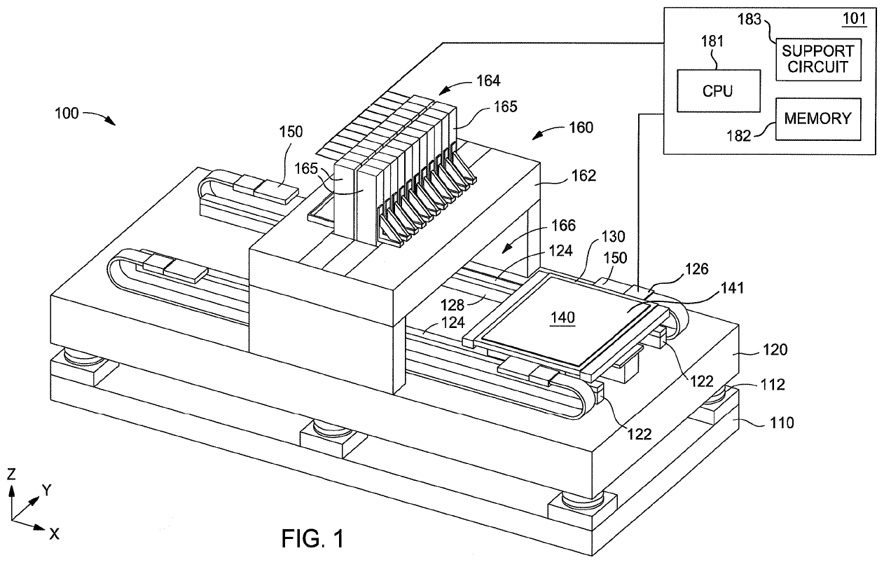

FIG. 1 is a schematic partial perspective view of a lithography system 100, according to one or more of the embodiments described herein. The lithography system 100 includes a base frame 110, a slab 120, a stage 130, and a processing apparatus 160. The base frame 110 rests on the floor of a fabrication facility and supports the slab 120. Passive air isolators 112 are positioned between the base frame 110 and the slab 120. In one embodiment, which can be combined with other embodiments, the slab 120 is a monolithic piece of granite, and the stage 130 is disposed on the slab 120. A substrate 140 is supported by the stage 130. A plurality of openings are formed in the stage 130 to allow a plurality of lift pins to extend therethrough. The lift pins raise to an extended position to receive the substrate 140, such as from one or more transfer robots. The one or more transfer robots are used to load and unload substrates, such as the substrate 140, to and from the stage 130.

The substrate 140 includes any suitable material, for example, glass used as part of a flat panel display. The substrate 140 can be made of other materials. The substrate 140 has a photoresist layer formed thereon. The photoresist layer is sensitive to radiation. A positive photoresist includes portions of the photoresist, which when exposed to radiation, will be respectively soluble to photoresist developer applied to the photoresist after the pattern is written into the photoresist. A negative photoresist includes portions of the photoresist, which when exposed to radiation, will be respectively insoluble to photoresist developer applied to the photoresist after the pattern is written into the photoresist. The chemical composition of the photoresist determines whether the photoresist will be a positive photoresist or negative photoresist. Examples of photoresists include, but are not limited to, one or more of diazonaphthoquinone, a phenol formaldehyde resin, poly(methyl methacrylate), poly(methyl glutarimide), and/or SU-8. During processing using the lithography system 100, a pattern is formed on a process surface 141 of the substrate 140 to form the electronic circuitry, such as electronic circuitry for use on a large-area flat panel display screen.

The lithography system 100 includes a pair of supports 122 and a pair of tracks 124. The pair of supports 122 are disposed on the slab 120, and the slab 120 and the pair of supports 122 are a single piece of material. The pair of tracks 124 are supported by the pair of the supports 122, and the stage 130 moves along the tracks 124 in the X-direction. The lithography system 100 can include one or more additional stages, in addition to the stage 130 illustrates. In one embodiment, which can be combined with other embodiments, the pair of tracks 124 is a pair of parallel magnetic channels. Each track 124 of the pair of tracks 124 is linear. In one embodiments, which can be combined with other embodiments, one or more of the tracks 124 is non-linear. An encoder 126 is coupled to the stage 130 in order to provide location information to a controller 101. The controller 101 includes a central processing unit (CPU) 181, a memory 182, and a support circuits 183, described in further detail below.

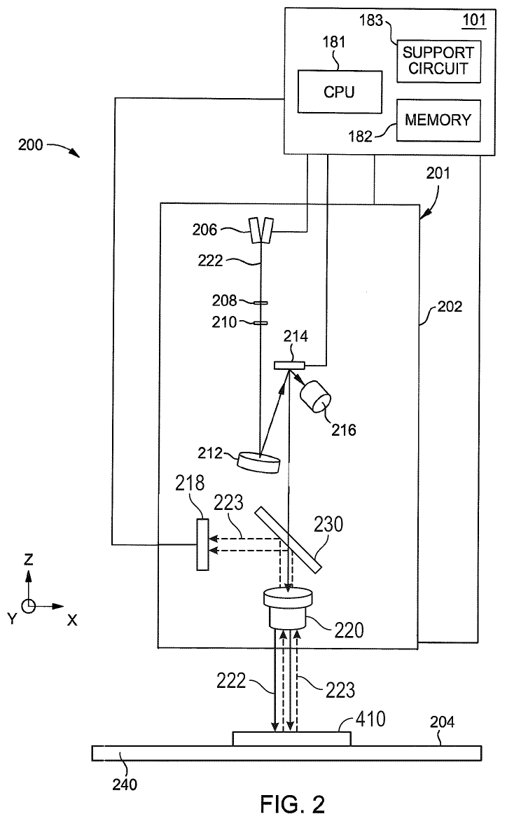

The processing apparatus 160 includes a support 162 and a processing unit 164. The support 162 is disposed on the slab 120 and includes an opening 166 for the stage 130 to pass under the processing unit 164. The processing unit 164 is supported by the support 162. In one embodiment, the processing unit 164 is a pattern generator configured to expose a photoresist in a photolithography process. In one embodiment, which can be combined with other embodiments, the pattern generator is configured to conduct a maskless lithography process. The processing unit 164 includes a plurality of image projection apparatus 200 (shown in FIG. 2). In one embodiment, which can be combined with other embodiments, the processing unit 164 includes as many as 84 or more image projection apparatus. Each image projection apparatus is disposed in a case 165. The processing apparatus 160 can be used to conduct maskless direct patterning.

During operation of the lithography system 100, the stage 130 moves in an X-direction from a loading position, as shown in FIG. 1, to a processing position. The processing position includes one or more positions of the stage 130 as the stage 130 passes under the processing unit 164. During operation, the stage 130 is lifted by a plurality of air bearings and moves along the pair of tracks 124 from the loading position to the processing position. A plurality of vertical guide air bearings are coupled to the stage 130 and positioned adjacent an inner wall 128 of each support 122 to stabilize the movement of the stage 130. The stage 130 also moves in a Y-direction by moving along a track 150 for processing and/or indexing the substrate 140. The stage 130 is capable of independent operation and can scan a substrate 140 in one direction and step in the other direction.

A metrology system measures the X and Y lateral position coordinates of each of the stage 130 in real time so that each of the plurality of image projection apparatus can accurately locate the patterns being written in a photoresist covered substrate. The metrology system also provides a real-time measurement of the angular position of each of the stage 130 about a vertical or Z-axis. The angular position measurement can be used to hold the angular position constant during scanning using a servo mechanism. The angular position measurement can be used to apply corrections to the positions of the patterns being written on the substrate 140 by the image projection apparatus 200, shown in FIG. 2. In one embodiment, which can be combined with other embodiments, these techniques are used in combination.

FIG. 2 is a perspective schematic view of an image projection apparatus 200 used in the lithography system 100 of FIG. 1 during an illumination operation, according to one or more of the embodiments described herein. The image projection apparatus 200 is used as each of the plurality of image projection apparatus corresponding to each of the cases 165 used in the lithography system 100 of FIG. 1. The image projection apparatus 200 includes an optical module 201. The optical module 201 includes a housing 202.

The image projection apparatus 200 directs a plurality of first light beams 222 toward an alignment mark 410 on a reflective surface 204 of a first substrate 240. The first substrate 240 may move in the X-direction and the Y-direction, as the first light beams 222 are directed toward the reflective surface 204. The first substrate 240 includes a mirror. In one embodiment, which can be combined with other embodiments, the reflective surface 204 is a continuous and planar surface.

The substrate 140 illustrated in FIG. 1 is patterned using the lithography system 100. The first substrate 240 illustrated in FIG. 2 is used to calibrate the lithography system 100, such as by adjusting the optical modules 201 of the image projection apparatus 200. Each of the image projection apparatus 200 includes a respective motor to control a tilt position, a tip position, and a vertical position of the respective optical module 201. The number of image projection apparatus 200 can vary based on the size of the substrate 140 and/or the speed of stage 130 (shown in FIG. 1).

The optical module 201 includes a light source 206, an aperture 208, a lens 210, a mirror 212, a digital mirror device (DMD) 214, a light dump 216, a camera 218, and a projection lens 220. The light source 206 includes light emitting diodes (LEDs) or lasers. In one example, the light source 206 includes a broadband LED. The light source 206 is capable of producing light beams having a predetermined wavelength. In one embodiment, which can be combined with other embodiments, the predetermined wavelength is in the blue or near ultraviolet (UV) range, such as 450 nm or less. The mirror 212 includes a spherical mirror. The camera 218 may include for example, a charge-coupled device (CCD) camera and/or a complementary metal oxide semiconductor (CMOS) camera.

The projection lens 220 includes an objective lens, such as a 10× objective lens. The DMD 214 includes a plurality of mirrors, and the number of mirrors of the DMD 214 may correspond to the resolution of the projected image.

During operation, first light beams 222 having a predetermined wavelength, such as a wavelength in the blue range, are emitted by the light source 206. The first light beams 222 are reflected to the DMD 214 using the mirror 212. The mirrors of the DMD 214 may be controlled individually, and each mirror of the plurality of mirrors of the DMD 214 may be set at an “on” position or an “off” position, based on pattern data. The pattern data may be provided to the DMD 214 using the controller 101. When the first light beams 222 reach the mirrors of the DMD 214, the mirrors that are at the “on” position reflect the first light beams 222 to direct the first light beams 222 through a beam splitter 230 and toward the projection lens 220 to be projected onto the alignment mark 410 of the reflective surface 204. The projection lens 220 directs the first light beams 222 to the reflective surface 204 of the first substrate 240. The mirrors that are at the “off” position reflect the first light beams 222 to direct the first light beams 222 to the light dump 216 instead of the reflective surface 204 of the first substrate 240.

The first light beams 222 reflect off the reflective surface 204 and are directed back toward the projection lens 220 as reflected first light beams 223. The reflected first light beams 223 are collected using at least the projection lens 220, and are directed toward the beam splitter 230. The reflected first light beams 223 reflect off the beam splitter 230 and are directed toward the camera 218. The beam splitter 230 is oriented such that at least a portion of the light beams projecting toward the beam splitter 230 from the DMD 214 pass through the beam splitter 230 and project toward the projection lens 220. The beam splitter 230 is oriented such that at least a portion of the light beams projecting toward the beam splitter 230 from the projection lens 220 are reflected toward the camera 218.

The camera 218 takes a plurality of first images of the image plane projected onto the reflective surface 204. The first images taken by the camera 218 include the reflected first light beams 223 that reflect off the alignment mark 410 of the reflective surface 204. The camera 218 transmits the plurality of first images including the reflected first light beams 223 to the controller 101.

The optical module 201 is moved vertically while the first light beams 222 are projected onto the reflective surface 204 and the camera 218 takes the first images that include the reflected first light beams 223. In one embodiment, which can be combined with other embodiments, the optical module 201 is moved vertically upward and/or downward along the Z-axis and relative to the first substrate 240. In one example, the optical module 201 moves across a plurality of vertical positions. In one embodiment, which can be combined with other embodiments, the first images taken using the camera 218 correspond to a plurality of vertical positions of the optical module 201. In one embodiment, which can be combined with other embodiments, the optical module 201 is disposed at a tip position and a tilt position while the optical module 201 moves vertically and the camera 218 takes the first images.

The projection lens 220 is part of a first illumination source that may be, e.g., a brightfield illumination source. The brightfield illumination source projects the first light beams 223 toward the reflective surface 204 within a field of view of the projection lens 220.

During calibration of the lithography system 100 using the first substrate 240, the first substrate 240 is not patterned by the first light beams 222. In one embodiment, which can be combined with other embodiments, the first substrate 240 does not include a photoresist layer formed thereon.

In the implementation shown in FIG. 2, the optical module 201 includes a spatial light modulator (SLM) that is a part of the illumination source. In the implementation shown, the SLM includes the DMD 214. The present disclosure contemplates that other SLM's and associated aspects thereof may be used in place of one or more aspects of the optical module 201 (such as in place of the DMD 214 and/or the light source 206). In one embodiment, which can be combined with other embodiments, the optical module 201 includes microLED arrays, vertical cavity surface emitting laser (VCSEL) arrays, and/or liquid crystal displays (LCD) arrays as part of the first illumination source. In one example, the microLED arrays, the VCSEL arrays, and/or the LCD arrays are used and one or more of the DMD 214, the light source 206, the aperture 208, the lens 210, the mirror 212, and/or the light dump 216 are omitted.

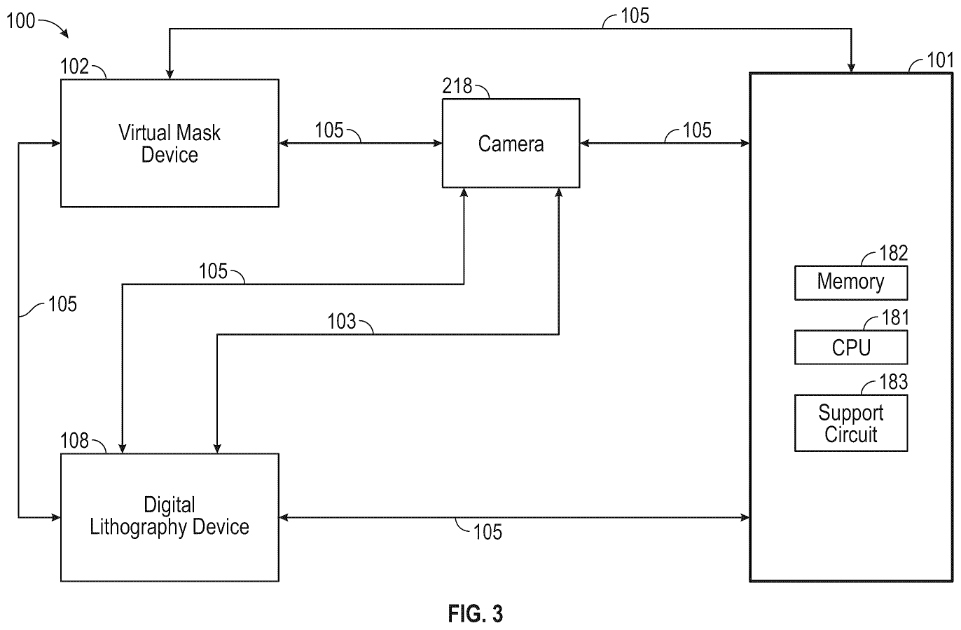

FIG. 3 is a schematic of the lithography system 100 of FIG. 1, according to one or more of the embodiments described herein.

As shown, the lithography system 100 includes, but is not limited to, a virtual mask device 102, a camera 218, a digital lithography device 108, a controller 101, and a plurality of communication links 105. The lithography system 100 may further include a transfer system 103. The digital lithography device 108 and the camera 218 may be connected by the transfer system 103. The transfer system 103 is operable to transfer a substrate between the digital lithography device 108 and the camera 218.

Each of the lithography system devices (the virtual mask device 102, the camera 218, the digital lithography device 108, and the controller 101) are operable to be connected to each other via the communication links 105. Alternatively or additionally, each of the lithography system devices can communicate indirectly by first communicating with the controller 101, followed by the controller 101 communicating with the lithography system device in question. The lithography system 100 can be located in the same area or production facility, or the each of the lithography system devices can be located in different areas.

The controller 101 includes the CPU 181, the support circuits 183 and memory 182. The CPU 181 can be one of any form of computer processor that can be used in an industrial setting for controlling the lithography system devices. The memory 182 is coupled to the CPU 181. The memory 182 can be one or more of readily available memory, such as random access memory (RAM), read only memory (ROM), floppy disk, hard disk, or any other form of digital storage, local or remote. The support circuits 183 are coupled to the CPU 181 for supporting the processor in a conventional manner. These circuits include cache, power supplies, clock circuits, input/output circuitry, subsystems, and the like. The controller 101 can include the CPU 181 that is coupled to input/output (I/O) devices found in the support circuits 183 and the memory 182. The controller 101 is operable to facilitate and transfer a design file to the digital lithography device 108 via the communication links 105.

The memory 182 can include one or more software applications, such as a controlling software program. The memory 182 can also include stored media data that is used by the CPU 181. The CPU 181 can be a hardware unit or combination of hardware units capable of executing software applications and processing data. In some configurations, the CPU 181 includes a central processing unit (CPU), a digital signal processor (DSP), an application-specific integrated circuit (ASIC), and/or a combination of such units. The CPU 181 is generally configured to execute the one or more software applications and process the stored media data, which can be each included within the memory 182. The controller 101 controls the transfer of data and files to and from the various lithography system devices. The memory 182 is configured to store instructions corresponding to any operation of the methods according to embodiments described herein.

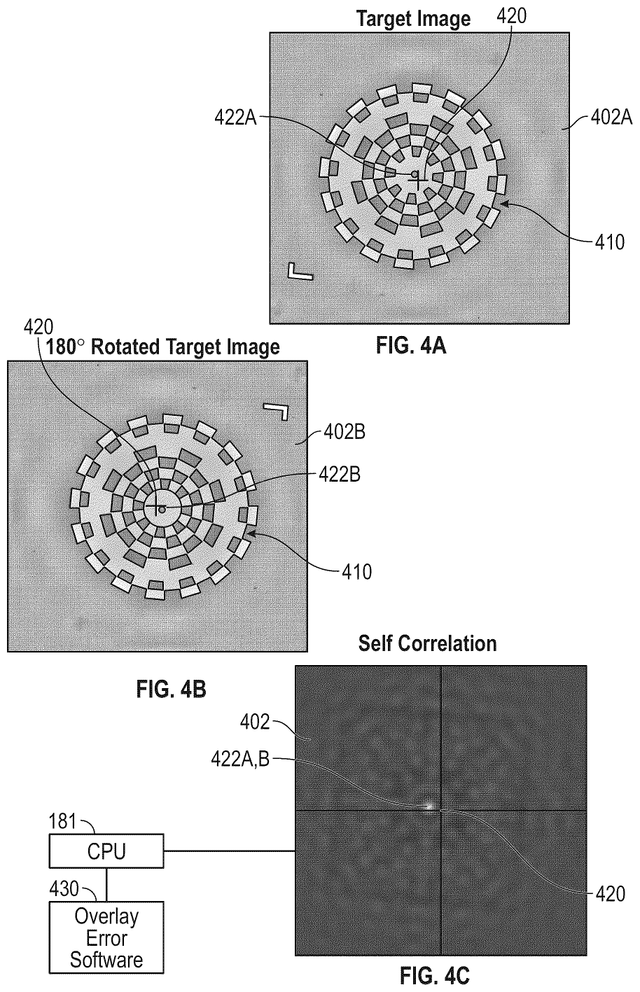

FIG. 4A illustrates a target image including an alignment mark, the target image indicating an actual center point of the target image and a predetermined center point of the rotation, according to one or more of the embodiments described herein.

The target image 402A is captured by the camera 218 of FIGS. 2 and 3. The target image 402A includes an alignment mark 410. The alignment mark 410 can include any variety of different patterns or shapes. In this example, the alignment mark 410 defines a plurality of patterns formed in as concentric circles.

The actual center point of the alignment mark 410 is determined. The actual center point 422A is represented as a dot. The actual center point 422A is the center point determined or calculated from the captured target image 402. A predetermined center point of the rotation is retrieved from, e.g., a database. The predetermined center point 420 is represented as a cross. The actual center point 422A and the predetermined center point 420 may be concurrently or simultaneously displayed on the alignment mark 410. The predetermined center point 420 identifies a known or expected location for the center or center point of the whole image. The predetermined center point 420 is fixed. In the instant case, the actual center point 422A is offset from the predetermined center point 420. Stated differently, there is a deviation between the actual center point 422A and the predetermined center point 420.

FIG. 4B illustrates the target image of FIG. 4A rotated by a first amount, according to one or more of the embodiments described herein.

The target image 402A is rotated by a first amount. In one example, the target image 402A is rotated by 180° to create rotated target image 402B. The rotation occurs around the selected or predetermined center point 420. The rotation of the target image 402A (to the rotated target image 402B) causes rotation of the alignment mark 410. The rotated target image 402B is stored in a memory device such as memory 182.

After rotation of the alignment mark 410, the center point of the alignment mark 410 is determined again. The actual center point 422B is displayed. The actual center point 422B is different than the actual center point 422A of the initial or original image. The predetermined center point 420 (center of rotation) is fixed and remains in the same position (as in the initial or original non-rotated position). In the instant case, the actual center point 422B is offset from the predetermined center point 420. Stated differently, there is a deviation between the actual center point 422B and the predetermined center point 420.

Therefore, according to FIGS. 4A and 4B, the center point of the alignment mark 410 is determined after rotating the target image 402A by 180°. Then, a positional relationship is established between the rotated image and the captured image as described in FIG. 4C. The positional relationship may be referred to as self-correlation.

FIG. 4C illustrates two times of a deviation between the actual center point of the target image and the predetermined center point of the rotation, according to one or more of the embodiments described herein.

In FIG. 4C, self-correlation is performed between the original or initial captured target image and the rotated target image.

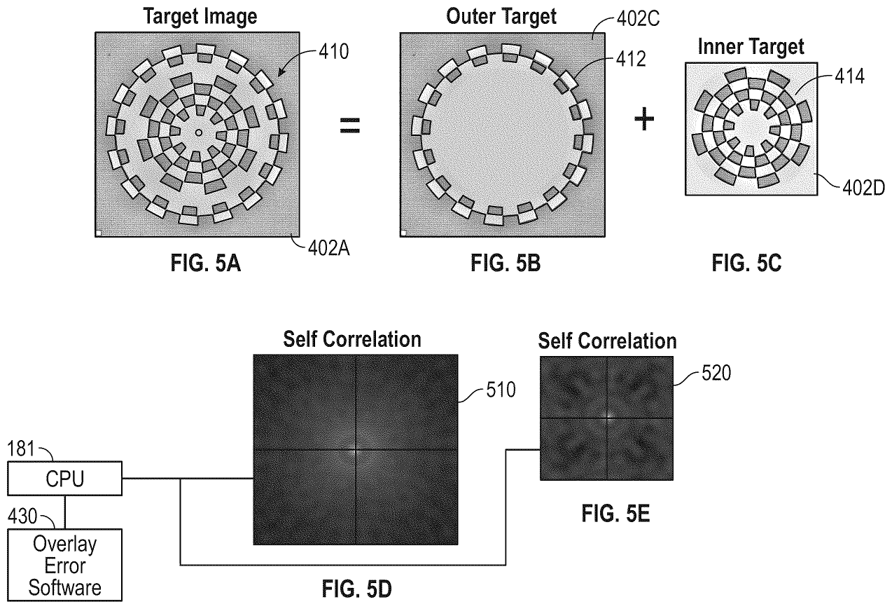

Self-correlation is defined as the correlation of an image with its 180° rotated image. Self-correlation may be referred to as a positional relationship between the captured image and the rotated image. The distance of a self-correlation peak from the rotation pivot is two times the distance of the center of the original (or non-rotated) target image from the rotation pivot. Thus, the distance of the center of the original (or non-rotated) target image is determined from the rotation pivot by halving the distance of self-correlation peak from the rotation pivot. This is how self-correlation is used to determine the positions of inner and outer targets separately (FIGS. 5A-5E).

The purpose of self-correlation (or positional relationships) is finding the center of the alignment mark 410 or overlay target without using any other image or image model, which is usually called a template. Self-correlation is a self-contained method. Self-containment provides an advantage because self-containment can tolerate a large amount of variations in image contrast, image blurring, image rotation, etc., which can happen frequently during semiconductor manufacturing due to film thickness or process variation. However, self-containment involves the generation of a 180° rotated pattern. The rotated pattern should be the same as the original non-rotated pattern except for its position. Therefore, the self-correlation method works only for 180° rotationally symmetric target patterns. This requirement of pattern symmetry may be a disadvantage. However, the gain obtained from the symmetry requirement is much greater than the loss caused by the symmetry requirement.

The self-correlation may be performed by overlay error software 430 executed by the CPU 181. The amount of self-correlation may be provided to the user. The self-correlation may be used to adjust the orientation of the camera 218 of FIGS. 1 and 2 or adjust the substrate 140 of FIG. 1 to obtain a better alignment between layers of a semiconductor structure.

FIGS. 4A-4C provide a first part of the process for determining self-correlation of an entire captured image. FIGS. 5A-5E provide a second part of the process for determining an overlay error based on separated portions of the captured image. The first part of the process assists in the automation of the overlay measurement process. During automated overlay measurements, a single measurement may not be enough to accurately determine the center of the alignment mark 410. As such, the first part of the process described in FIGS. 4A-4C provides for an automated finding of the center of alignment mark. To provide for overlay measurement, a second automated process is performed. The second part of the process described below with reference to FIGS. 5A-5E provides for the automated overlay measurement. The combination of the first part and the second part of the process provides for a more accurate overlay measurement calculation.

FIG. 5A illustrates a target image including an alignment mark, according to one or more of the embodiments described herein.

The target image 402A is captured by the camera 218 of FIGS. 2 and 3. The target image 402A includes an alignment mark 410. The alignment mark 410 can include any variety of different patterns or shapes. In this example, the alignment mark 410 defines a plurality of patterns formed in as concentric circles. At this point of the second part of the process, no center points are determined. Instead, the target image 402A is first separated into two sections or segments or sections before any center point determination is made.

As such, the target image 402A is separated into two portions. The first portion is referred to as a first alignment mark portion 412 or an outer target image portion. The second portion is referred to as a second alignment mark portion 414 or an inner target image portion. The first alignment mark portion 412 may include the outer design of the alignment mark 410 and the second alignment mark portion 414 may include the inner design of the alignment mark 410. Stated differently, the outer concentric circle patterns can be referred to as the first alignment mark portion 412 and the inner concentric circle patterns can be referred to as the second alignment mark portion 414.

FIGS. 5B-5C illustrate separating the target image of FIG. 5A including the alignment mark into a first alignment mark portion and a second alignment mark portion, according to one or more of the embodiments described herein.

FIG. 5B depicts the first alignment mark portion 412 (outer target section) and FIG. 5C depicts the second alignment mark portion 414 (inner target section). The image including the first alignment mark portion 412 may be designated as image portion 402C and the image including the second alignment mark portion 414 may be designated as image portion 402D. As shown, the alignment mark 410 has been separated or divided into two portions or sections or segments, that is, an outer portion and an inner portion.

A predetermined center point of the rotation is retrieved. The first alignment mark portion 412 is then rotated by a first amount, e.g., 180°, to obtain a rotated first alignment mark. The first alignment mark portion 412 is rotated about the center point of the rotation.

The predetermined center point of the rotation is retrieved. The second alignment mark portion 414 is then rotated by a first amount, e.g., 180°, to obtain a rotated second alignment mark. The second alignment mark portion 414 is rotated about the center point of the rotation.

Therefore, each separated image (that is, 402C and 402D) is rotated (about the selected center point of rotation) to obtain separate and distinct center point offsets. The first center point offset or deviation results from the first alignment mark portion 412 and the second center point offset or deviation results from the second alignment mark portion 414.

It is noted that the first alignment mark portion 412 may be printed by an image projection apparatus 200 and the second alignment mark portion 414 may be printed by another image projection apparatus 200. Or, the first alignment mark portion 412 may be printed on a thin film layer and the second alignment mark portion 414 may be printed on another thin film layer

FIGS. 5D-5E illustrate performing self-correlation individually to the first alignment mark portion and the second alignment mark portion, according to one or more of the embodiments described herein.

FIG. 5D illustrates self-correlation being performed on the first alignment mark portion 412 between the target image and the rotated image.

FIG. 5E illustrates self-correlation also being performed on the second alignment mark portion 414 between the target image and the rotated image.

Therefore, after the target image 402A is separated, there are two instances of self-correlation. The first instance of self-correlation is applied to the outer target and the second instance of self-correlation is applied to the inner target. As such, there are a total of three instances of self-correlation. One self-correlation is performed in the first part of the process described in FIGS. 4A-4C and two more self-correlations are performed in the second part of the process described in FIGS. 5A-5E. All three self-correlations combined offer a more accurate overlay measurement.

Overlay error is a relative distance between the inner target and the outer target. If the inner target and outer target are the same or very similar patterns except for their positions, their relative distance can be determined by correlating the two patterns. This is the simplest way to determine the overlay error. However, this simple method is not beneficial because the inner and outer target patterns cannot be the same or similar. If the two patterns are different, correlation cannot produce any meaningful number. Consequently, the positions of the inner and outer targets are separately determined and then the relative distance between the two targets is calculated to determine the overlay error. In order to determine the positions of the two targets separately, self-correlation is applied two times separately, one for the position determination of inner target and the other for the position determination of outer target. This self-correlation is also referred to as establishing a positional relationship between the captured image and the rotated image.

The self-correlation may be performed by overlay error software 430 executed by the CPU 181. The amount of self-correlation may be provided to the user. The self-correlation may be used to adjust the position of printed images or the position of the camera 218 of FIGS. 1 and 2 or adjust the substrate 140 of FIG. 1 to obtain a better alignment between layers of a semiconductor structure.

According to FIGS. 1-5E, the overlay error is computed for the alignment mark 410. However, the alignment mark 410 is one of many alignment marks on the substrate 140 of FIG. 1. The alignment marks may be positioned on scribe lines between die on the substrate. The lithography system 100 includes a plurality of image projection apparatuses 200 each including a camera 218. In one example, there are 22 image projection apparatuses 200. Thus, there are 22 cameras 218. Each camera 218 may detect a different alignment mark. In the instant example, if there are 22 cameras, then 22 different alignment marks may be captured. An overlay error may be computed for each of the 22 different alignment marks. After the overlay error is computed for each of the 22 alignment marks detected from the 22 cameras, alignment corrections may be applied to each of the alignment marks.

Moreover, each camera can also be referred to as an eye. The example embodiments perform eye-to-eye calibration and eye-to-eye stitching. The array of eyes or cameras are used to print patterns on the substrate 140. The array of cameras work in unison as one overall camera to perform the printing. Thus, each camera should be calibrated such that all the cameras work together as one calibrated unit. Eye-to-eye stitching is employed to connect or couple the pattern portions or pieces into one pattern to create one uniform image. In one example, metrology may be used to determine whether the image was properly stitched together between each of the cameras or eyes. Also, by determining the overlay error of each alignment mark captured by the cameras 218, the hardware or software of cameras 218 can be adjusted based on the overlay error measurement so that proper eye-to-eye stitching may be performed.

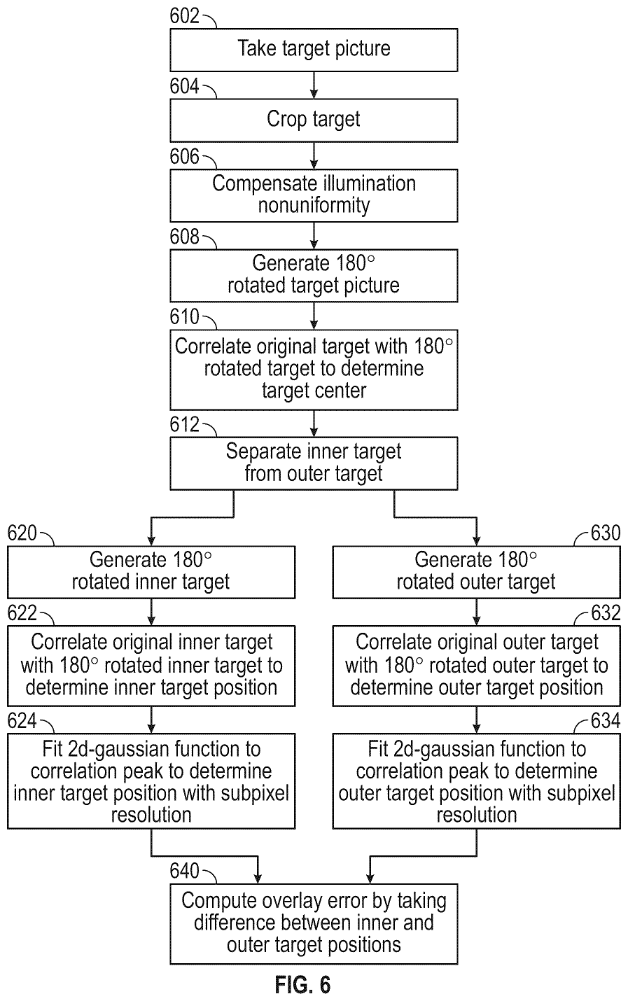

FIG. 6 is a method for computing an overlay error to perform proper alignment of material layers, according to one or more of the embodiments described herein.

In block 602, a target image is captured by a camera. The target image includes, e.g., an alignment mark. The camera may be a camera of the image projection apparatus 200 of FIG. 2 incorporated in the lithography system 100 of FIG. 1.

In block 604, the captured target image may optionally be cropped. In other words, unwanted parts of the captured image may be removed to focus on a specific element, that is, the alignment mark.

In block 606, the system may compensate for illumination non-uniformity. Illumination non-uniformity refers to the uneven distribution of light intensity across the exposure field. In lithography, a pattern is transferred onto a substrate coated with a photosensitive material (photoresist) using light. This process employs uniform illumination to ensure that the pattern is accurately replicated across the entire surface of the substrate. However, due to various factors such as the design of the illumination system, optics imperfections, diffractive effects, and variations in the light source, the intensity of light reaching different parts of the exposure field may vary. This non-uniformity may lead to deviations in the printed features, affecting the quality and precision of the final semiconductor device. To mitigate illumination non-uniformity, the example embodiments may employ techniques such as optical corrections, adjusting the design of the illumination system, optimizing the light source, and employing software-based compensation methods. In one example, non-uniformity illumination may be corrected by applying a Legendre polynomial fitting to the captured image.

In block 608, the captured target image is rotated by a first amount, e.g., 180°. The target image may be rotated by other amounts depending on the application.

In block 610, self-correlation is performed between the original or initial captured target image and the rotated target image. Self-correlation refers to a comparison between actual center points of the original or initial captured target image and the rotated target image. In other words, the actual center point of the original target image is compared to the actual center point of the rotated target image. This comparison between the two center points provides for the deviation between the center points of the original target image and the rotated target image. This process provides an accurate position of the center of whole alignment mark. This positional information facilitates more accurate re-cropping of alignment mark image and more accurate target separation in the second part of overlay measurement process. The comparison between the center points of the two orientations of the target image can be referred to as self-correlation. This is the first part of the overlay measurement process, which may be referred to as a two-step process.

In block 612, the target image captured by the camera 218 of FIGS. 2 and 3 is separated into two portions or two segments or two sections or two parts. This commences the second part of the overlay measurement process. The first portion is referred to as a first alignment mark portion or an outer target image portion. The second portion is referred to as a second alignment mark portion or an inner target image portion. The first alignment mark portion may include the outer design of the alignment mark and the second alignment mark portion may include the inner design of the alignment mark.

In block 620, the second alignment mark portion (inner target image) is rotated by a first amount, e.g., 180°.

In block 622, an actual center point of the second alignment mark portion is determined by performing self-correlation, which correlates the second alignment mark with the rotated second alignment mark by performing self-correlation.

In block 624, 2D Gaussian function fitting to the correlation peak is performed.

2D Gaussian function fitting is a mathematical technique used to model and analyze data that exhibits a Gaussian (bell-shaped) distribution in two dimensions. The 2D Gaussian function fitting involves finding parameters that best describe the observed data. This is often done by minimizing the difference between the observed data and the modeled Gaussian function using optimization techniques such as least squares fitting. Once the parameters are determined, the 2D Gaussian function may be used to describe and analyze the underlying distribution of the data, extract features such as the peak position.

Fitting a 2D Gaussian function to an image allows for the extraction of key parameters such as the center coordinates and the standard deviations in the x and y directions, providing insights into the distribution of intensity or features within the image. When performing Gaussian fitting for image analysis, achieving subpixel resolution becomes crucial for accurately determining the location and size of features.

The 2D Gaussian fitting procedure uses a fitting algorithm (e.g., least squares fitting) to fit the defined Gaussian function to the image data. The fitting algorithm supports subpixel resolution by allowing for fractional pixel shifts in the Gaussian center. For, the subpixel resolution techniques such as interpolation or refinement algorithms are implemented to obtain subpixel resolution in the fitted Gaussian parameters. The system evaluates the goodness of fit to determine the quality of the Gaussian fit to the image data. In the example embodiments, the 2D Gaussian function fitting is applied to a positional relationship peak for subpixel resolution after acquiring pixelwise (i.e., a single pixel) resolution of the positional relationship peak.

In block 630, after the inner target self-correlation is complete, the first alignment mark portion (outer target image) is rotated by a first amount, e.g., 180°.

In block 632, an actual center of the first alignment mark portion is determined by performing self-correlation, which correlates the first alignment mark with the rotated first alignment mark.

In block 634, 2D Gaussian function fitting to the correlation peak is performed.

In block 640, an overlay error is computed by taking the difference between the inner target position and the outer target position.

Therefore, FIGS. 4A-4C provide a first part of the process for determining the center of whole alignment mark. FIGS. 5A-5E provide a second part of the process for determining an overlay error. The first part of the process assists in the automation of the overlay measurement process. During automated overlay measurements, a single measurement may not be enough to accurately determine the location of alignment target. As such, the first part of the process described in FIGS. 4A-4C provides for an automated finding of the exact location of alignment target. The second part of the process described with reference to FIGS. 5A-5E provides for the automated overlay measurement. The combination of the first part and the second part of the process provides for a more accurate overlay measurement calculation. The first part of the process provides for an acceptable approximation of finding the target position. The second part of the process provides for an accurate overlay measurement. The first part of the process involves performing a single self-correlation, whereas the second part of the process involves performing two additional self-correlations. By combining the three self correlations in the two-part overlay measurement process, more accurate target positioning may be obtained.

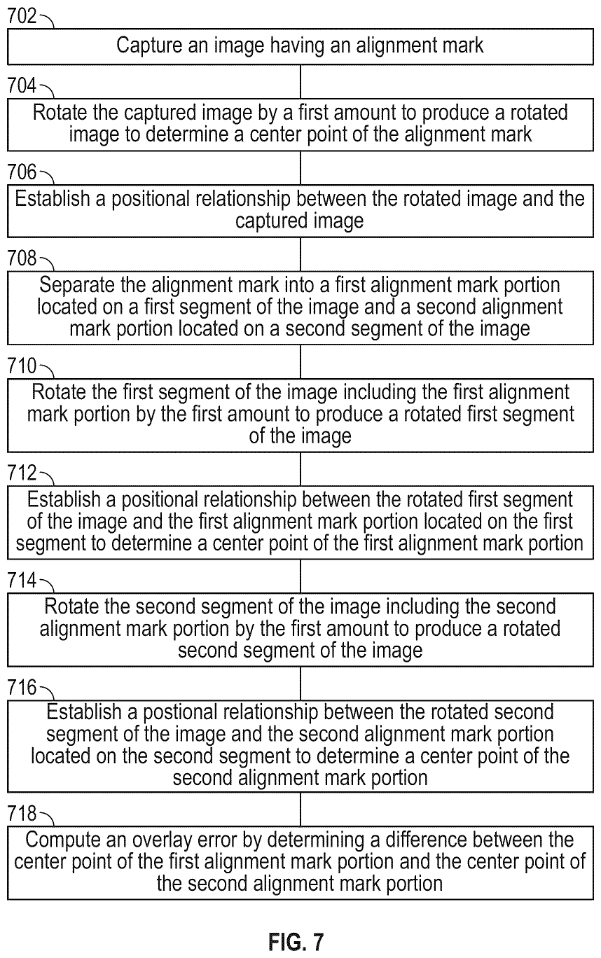

FIG. 7 is a method for computing an overlay error between the first alignment mark portion and the second alignment mark portion, according to one or more of the embodiments described herein.

In block 702, an image having an alignment mark is captured by a camera. The image may be referred to as a target image.

In block 704, the captured image is rotated by a first amount to produce a rotated image to determine a center point of the alignment mark.

In block 706, a positional relationship is established between the rotated image and the captured image.

In block 708, the alignment mark is separated into a first alignment mark portion located on a first segment of the image and a second alignment mark portion located on a second segment of the image.

In block 710, the first segment of the image including the first alignment mark portion is rotated by the first amount to produce a rotated first segment of the image.

In block 712, a positional relationship is established between the rotated first segment of the image and the first alignment mark portion located on the first segment to determine a center point of the first alignment mark portion.

In block 714, the second segment of the image including the second alignment mark portion is rotated by the first amount to produce a rotated second segment of the image.

In block 716, a positional relationship is established between the rotated second segment of the image and the second alignment mark portion located on the second segment to determine a center point of the second alignment mark portion.

In block 718, an overlay error is computed by determining a difference between the center point of the first alignment mark portion and the center point of the second alignment mark portion.

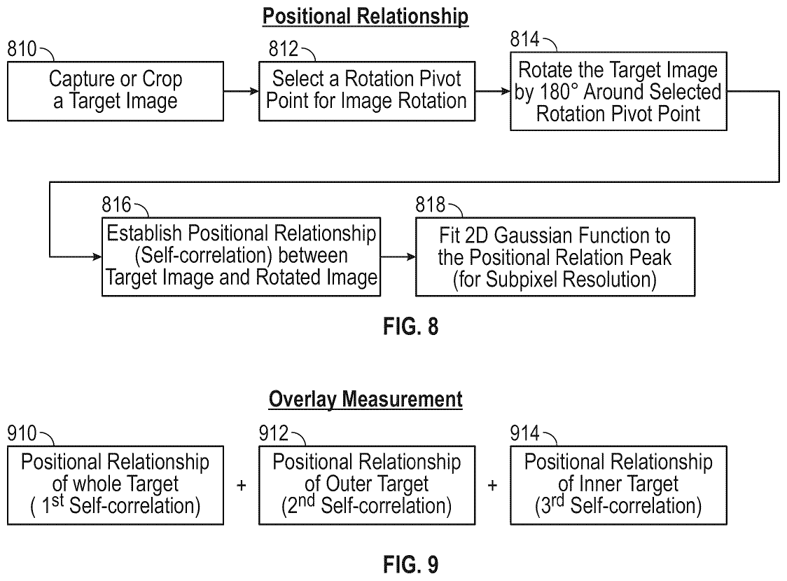

FIG. 8 illustrates a process of establishing positional relationships, according to one or more of the embodiments described herein.

In block 810, a target image is captured or cropped. The target image can include an alignment mark. The target image can be the whole target or an outer target or an inner target.

In block 812, a rotation pivot point is selected for image rotation. The rotation pivot point is the center of rotation.

In block 814, the target image is rotated by 180° around the selected rotation pivot point or center or rotation. The rotated image is stored in a memory device.

In block 816, a positional relationship is established between the target image and the rotated image. The positional relationship refers to self-correlation. In other words, the target image and the rotated image are correlated. This results in obtaining a positional relationship with single-pixel resolution.

In block 818, a 2D Gaussian function is fitted to the positional relation peak to achieve subpixel resolution.

FIG. 9 illustrates a process for determining an overlay measurement employing the positional relationship process three times, according to one or more of the embodiments described herein.

In block 910, the positional relationship of the whole target is obtained.

The whole target is usually cropped two times because the exact location of the whole target in the first cropping is not known. The whole target can be partially clipped or quite decentered in the first time cropping. Thus, a positional relationship process is applied to the first time-cropped whole target to acquire the center of the whole target accurately enough. The acquired center of the whole target is used to crop the whole target image a second time to avoid any clipping or excessive decentering.

In block 912, the positional relationship of the outer target is obtained. As such, the center point of the outer target is determined.

In block 914, the positional relationship of the inner target is obtained. As such, the center point of the inner target is determined.

Therefore, in FIG. 9, self-correlation is applied three times in order to determine the overlay error.

In summary, the example embodiments present overlay techniques to measure overlay accurately when aligning different layers of patterns during lithography steps or aligning two patterns printed by different eyes. In one example, the overlay technique to measure overlay accuracy when aligning same or different layers of patterns during lithography steps. In one example, the overlay technique involves capturing an image of an alignment mark, rotating the captured image by a first amount, e.g., 180° to determine a center point of the alignment mark, and establishing a positional relationship between the rotated image and the captured image. The establishment of the positional relationship may also be referred to as self-correlation. Further, the overlay technique involves capturing an image of an alignment mark, separating the alignment mark into a first alignment mark portion and a second alignment mark portion, performing self-correlation on the first alignment mark portion, performing self-correlation on the second alignment mark portion, and computing an overlay error by taking a difference between the position of self-correlation peak on the first alignment mark portion and the position of self-correlation peak on the second alignment mark portion.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may be suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A method for operating a lithography system, the method comprising:
capturing an image having an alignment mark;
rotating the image to define a rotated image with a rotated alignment mark;
establishing a positional relationship between the rotated image and the captured image;
separating the alignment mark into a first alignment mark portion and a second alignment mark portion;
performing a first self-correlation on the first alignment mark portion and a second self-correlation on the second alignment mark portion; and
computing an overlay error by taking a difference between a position of self-correlation peak of the first alignment mark portion and a position of self-correlation peak of the second alignment mark portion.

2. The method of claim 1, wherein the image is rotated by 180°.

3. The method of claim 1, wherein the rotated image is symmetric to the captured image.

4. The method of claim 1, wherein the first alignment mark portion includes an outer section of the alignment mark and the second alignment mark portion includes an inner section of the alignment mark.

5. The method of claim 1, wherein illumination non-uniformity compensation is applied for accurate overlay measurement before the rotated image is produced.

6. The method of claim 1, wherein 2D Gaussian function fitting is applied to a positional relationship peak for subpixel resolution after acquiring pixelwise resolution of the positional relationship peak.

7. A method for operating a lithography system, the method comprising:
separating an alignment mark into a first alignment mark portion located on a first segment of an image and a second alignment mark portion located on a second segment of the image;
rotating the first segment of the image including the first alignment mark portion by a first amount to produce a rotated first segment of the image;
establishing a positional relationship between the rotated first segment of the image and the first alignment mark portion located on the first segment to determine a center point of the first alignment mark portion;
rotating the second segment of the image including the second alignment mark portion by the first amount to produce a rotated second segment of the image; and
establishing a positional relationship between the rotated second segment of the image and the second alignment mark portion located on the second segment to determine a center point of the second alignment mark portion.

8. The method of claim 7, further comprising computing an overlay error by determining a difference between the center point of the first alignment mark portion and the center point of the second alignment mark portion.

9. The method of claim 8, wherein the overlay error is determined by taking a difference between a positional relationship peak on the first alignment mark portion and a positional relationship peak on the second alignment mark portion.

10. The method of claim 7, wherein the first amount of rotation is 180°.

11. The method of claim 7, wherein the first alignment mark portion includes an outer section of the alignment mark.

12. The method of claim 11, wherein the second alignment mark portion includes an inner section of the alignment mark.

13. The method of claim 7, wherein illumination non-uniformity compensation is applied for subpixel resolution before the rotated first segment of the image and the rotated second segment of the image are produced.

14. The method of claim 7, wherein 2D Gaussian function fitting is applied to a positional relationship peak for subpixel resolution after acquiring pixelwise resolution of the positional relationship peak.

15. A non-transitory computer-readable medium comprising instructions that, when executed, cause a lithography system to:
capture an image having an alignment mark;
rotate the captured image by a first amount to produce a rotated image to determine a center point of the alignment mark;
establish a positional relationship between the rotated image and the captured image;
separate the alignment mark into a first alignment mark portion located on a first segment of the image and a second alignment mark portion located on a second segment of the image;
rotate the first segment of the image including the first alignment mark portion by the first amount to produce a rotated first segment of the image;
establish a positional relationship between the rotated first segment of the image and the first alignment mark portion located on the first segment to determine a center point of the first alignment mark portion;
rotate the second segment of the image including the second alignment mark portion by the first amount to produce a rotated second segment of the image;
establish a positional relationship between the rotated second segment of the image and the second alignment mark portion located on the second segment to determine a center point of the second alignment mark portion; and
compute an overlay error by determining a difference between the center point of the first alignment mark portion and the center point of the second alignment mark portion.

16. The non-transitory computer-readable medium of claim 15, wherein the rotated image is rotationally symmetric to the captured image.

17. The non-transitory computer-readable medium of claim 15, wherein the first alignment mark portion includes an outer section of the alignment mark and the second alignment mark portion includes an inner section of the alignment mark.

18. The non-transitory computer-readable medium of claim 15, wherein illumination non-uniformity compensation is applied for accurate overlay measurement before the rotated image is produced.

19. The non-transitory computer-readable medium of claim 15, wherein 2D Gaussian function fitting is applied to a positional relationship peak for subpixel resolution after acquiring pixelwise resolution of the positional relationship peak.

20. The non-transitory computer-readable medium of claim 15, wherein the overlay error is determined by taking a difference between a positional relationship peak on the first alignment mark portion and a positional relationship peak on the second alignment mark portion.
